(19) United States
(12) Patent Application Publication
(10) Pub. No.: US 2011/0057280 A1
(43) Pub. Date: Mar. 10, 2011

(54) COLOR IMAGING DEVICE AND COLOR IMAGING DEVICE FABRICATING METHOD

(75) Inventors: Motoi Kawamura, Kyoto (JP); Norihisa KITAMURA, Shiga (JP)

(73) Assignee: Panasonic Corporation, Osaka (JP)

(21) Appl. No.: 12/948,102

(22) Filed: Nov. 17, 2010

Related U.S. Application Data
(63) Continuation of application No. PCT/JP2009/004161, filed on Aug. 27, 2009.

(30) Foreign Application Priority Data
Aug. 29, 2008 (JP) 2008-221215

(51) Int. Cl. H01L 31/0232; H01L 31/18

(52) U.S. Cl. 257/432; 438/70; 257/E31.127

(57) ABSTRACT

In a color imaging device in which a color filter layer is formed respectively for a plurality of photoelectric conversion elements arranged on a substrate, the color filter layer comprises an underlying layer of a transparent resin and a pigment layer. The pigment layer is heat fused on the underlying layer. A heat treatment temperature for heat fusing is at or above a glass transition temperature of the transparent resin constituting the underlying layer.

### CROSS-REFERENCE TO RELATED APPLICATION

This is a continuation of International Application No. PCT/JP2009/004161 filed on Aug. 27, 2009, which claims priority to Japanese Patent Application No. 2008-221215 filed on Aug. 29, 2008. The disclosures of these applications including specifications, drawings and claims are incorporated herein by reference in their entireties.

### BACKGROUND OF THE INVENTION

1. Field of the Invention

The present invention relates to an imaging device and a fabricating method thereof and more particularly relates to a structure of a color filter that constitutes an imaging device and a formation method of the color filter.

2. Description of the Related Art

Advancements are presently being made for higher pixelization and micronization in imaging devices used in such as digital cameras and video cameras for a purpose of increasing pixel resolution for imaging.

FIG. 4 is a partial cross-sectional view showing a structure of a conventional color imaging device 10. The color imaging device 10 is formed by using a semiconductor substrate 11 made of silicon. A plurality of photoelectric conversion elements 12 for generating electric charges according to incident light is arranged in a matrix configuration and provided in a surface portion of the semiconductor substrate 11. A single pixel will normally provide a single photoelectric conversion element 12. FIG. 4 shows a region that corresponds to nearly 2 pixels of the color imaging device 10.

A dielectric film 13 covering the photoelectric conversion element 12 is formed on the semiconductor substrate 11. An anti-reflection film 14 for inhibiting reflection of light which enters the photoelectric conversion element 12 is formed on the photoelectric conversion element 12 with the dielectric film 13 interposed therebetween. A charge transfer electrode 15 for reading out the electric charges from each photoelectric conversion element 12 and transferring the readout electric charges is formed on areas of both sides of the photoelectric conversion element 12 on the semiconductor substrate 11 with the dielectric film 13 interposed therebetween. Further, a light shielding film 16 that shields light from entering the charge transfer electrode 15 is formed covering the charge transfer electrode 15. A charge transfer path 17, by which the readout electric charges are transferred, is provided in the semiconductor substrate 11 below the charge transfer electrode 15.

A transparent planarizing film 18 for planarization of a surface is formed covering the anti-reflection film 14 and the light shielding film 16 and the like. A color filter 19a and a color filter 19b of individual colors corresponding to the individual photoelectric conversion elements 12 are further formed thereabove. Although FIG. 4 shows only two color filters, a combination of, for example, the three colors of red, blue and green may be used as the colors for the color filters. A micro lens 20 is formed on each color filter 19a, 19b in a position which corresponds with each photoelectric conversion element 12.

The micro lens 20 improves a light condensing efficiency for each photoelectric conversion element 12.

Herein, in the color imaging device 10, a thickness between the photoelectric conversion element 12 and the micro lens 20 must be reduced in accordance with a progress in miniaturization of pixel size. If the thickness were to remain the same while the miniaturization advanced only with pixel size, an aspect ratio of the thickness of layers formed on the photoelectric conversion element to a dimension of the photoelectric conversion element would increase. When the aspect ratio increases, the condensing of incident light by the micro lens on the photoelectric conversion element becomes difficult and desensitization occurs in the imaging device.

In order to prevent this kind of desensitization, the thickness of the layers on the photoelectric conversion element must be thinner in accordance with the micronization of the imaging device.

In the conventional color imaging device 10, the layers on the photoelectric conversion element 12 comprise the planarizing film 18 and the color filters 19a, 19b, and the thickness thereof is about 2 μm. The thickness of each of the color filters 19a, 19b represents 20 to 40% of this thickness. Accordingly, thinning of the color filters 19a, 19b are effective for thinning the thickness of the layers on the photoelectric conversion element 12.

The conventional color filter is formed by photolithography patterning of a photosensitive resin containing a pigment. When using this technique, specified amounts of photo active compound and curing agent must be contained in the photosensitive resin for photolithography patterning. In addition, an amount of pigment contained within the photosensitive resin is limited in order to maintain performance as a photosensitive resin. Therefore, in order to obtain required spectral characteristics on the color filter formed by using the conventional photolithography patterning, a given thickness is required for the color filter. Therefore, a degree of thinning for the conventional color filter has been limited.

In order to resolve this problem, a method is proposed for making a color filter by patterning a vapor-deposited pigment film which is formed by depositing a pigment that does not have photosensitivity using vacuum deposition method.

For example, a prior document 1 (Japanese Laid Open Patent Application Publication No. H4-336503) discloses a method for patterning by using lift-off technique. A prior document 2 (Japanese Laid Open Patent Application Publication No. 2002-305295) discloses a method for patterning by using dry etching a deposited pigment layer.

### SUMMARY OF THE INVENTION

However, in the methods described above for patterning the vapor-deposited pigment film, there is a problem in that the vapor-deposited pigment film is easily exfoliated from a substrate.

First, a description will be given of the patterning of the vapor-deposited pigment film of the prior document 1 with reference to FIGS. 5A to 5E. As shown in FIG. 5A, a photoresist film 31 is formed by coating on a substrate 30 where a photoelectric conversion element and planarizing film are formed. Next, as shown in FIG. 5B, the photo resist film 31 is exposed by irradiation of ultraviolet light 33 through a photomask 32 having a desired pattern. In this way, the photo resist film 31 is divided into a resist pattern 31a, which is a portion that did not receive ultraviolet irradiation, and an exposed portion 31b which is a portion that is received ultraviolet irradiation. Next, as shown in FIG. 5C, the exposed portion 31b is removed by development process and rinse process to obtain a structure where the resist pattern 31a remains on the substrate 30. In this condition, when depositing the pigment, respective pigment films 34 are formed on the resist pattern 31a and on the substrate 30 as shown in FIG. 5D. The pigment film 34 on the resist pattern 31a is simultaneously removed with removal of the resist pattern 31a, to form a color filter made of the pigment film 34a patterned on the substrate 30 as shown in FIG. 5E.

Next, a description will be given of the patterning of the vapor-deposited pigment film of the prior document 2 with reference to FIGS. 6A to 6F. As shown in FIG. 6A, a pigment layer 51 is formed on a substrate 50 where a resin layer is formed as the topmost layer. Next, as shown in FIG. 6B, a photoresist film 52 is formed by coating on the pigment layer 51. Next, as shown in FIG. 6C, the photoresist film 52 is exposed with irradiation of ultraviolet light 54 through a photomask 53 having a desired pattern. In this way, the photoresist film 52 is divided into a resist pattern 52a, which is a portion that did not receive ultraviolet irradiation, and an exposed portion 52b which is a portion that is received ultraviolet irradiation. Next, as shown in FIG. 6D, through development process, the exposed portion 52b is removed to obtain a structure where the resist pattern 52a remains on the pigment layer 51. As shown in FIG. 6E, a portion of the pigment layer 51 on which the resist pattern 52a is not formed is removed by dry etching with the resist pattern 52a as a mask. After removing the resist pattern 52, a color filter made of pigment film 51a patterned on the substrate 50 is formed as shown in FIG. 6F,

With either method described in prior documents 1 and 2, the vapor-deposited pigment film is formed by depositing, for example, three colors of pigment, red, blue and green, that do not have photosensitivity onto the substrate where a planarizing film and the like is formed (hereinafter, a film-formed substrate will be referred to simply as a substrate), and the color filter is formed by patterning these vapor-deposited pigment films. In other words, each vapor-deposited pigment film is exposed to resist developing solution and resist removing solution in the development process, the rinse process and the removal process of the resist pattern and. Therefore, in a case that adhesiveness between the substrate and the vapor-deposited pigment film is poor, the vapor-deposited pigment film is exfoliated from the substrate during the development process or the removal process.

The adhesiveness between a thin film and a substrate depends on energy of sublimated particles. In vapor deposition method, the sublimated particle has a low energy. Therefore, the vapor-deposited pigment film deposited by vapor deposition method has poor adhesiveness with the substrate due to insufficient energy to form a strong bonding state with the substrate, so that the vapor-deposited pigment film has a problem that exfoliation occurs more easily do to patterning of the vapor-deposited pigment film.

In view of the above problems, the purpose of the present invention is to provide an imaging device including a color filter that has a pigment layer and a fabrication method thereof that provide stable adhesiveness to the pigment layer even in a thinned color filter.

In order to achieve the above purpose, a color imaging device relating to the present invention is a color imaging device in which a color filter layer is formed respectively for a plurality of photoelectric conversion elements arranged on a substrate. The color filter layer comprises an underlying layer of a transparent resin, and a pigment layer heat fused on the underlying layer at or above a glass transition temperature of the transparent resin constituting the underlying layer.

According to this structure, because the underlying layer made of the transparent resin and the pigment layer are heat fused at or above the glass transition temperature of the transparent resin, an anchoring effect is generated due to embedment of a part of the pigment layer into the underlying layer thereby improving the adhesiveness between the pigment layer and the underlying layer. Therefore, the problem in which the pigment layer is exfoliated from the underlying layer is eliminated even when the pigment layer is patterned. Accordingly, the color filter layer can be composed with the underlying layer of a thickness that only enables film formation by coating and the pigment layer which contains a pigment as a main component material (that does not contain a photo active component, curing agent and the like), so that the thickness of the color filter layer can be made thinner compared to the color filter made of the photosensitive resin layer. Herein, the pigment layer may also be composed solely of pigment.

As a result, because the thickness of the films on the photoelectric conversion element can be thinner while increasing the adhesive strength of the pigment layer, incident light can be effectively condensed to the photoelectric conversion element and desensitization which accompanies micronization of pixels can be avoided.

In the above structure, it is preferable that the underlying layer is a planarizing layer formed on the substrate in which the plurality of the photoelectric conversion elements is arranged.

When composing the underlying layer with the planarizing layer of the transparent resin, a part of the pigment layer included in the color filter layer is embedded in the planarizing layer and increases the adhesive strength between the planarizing layer and the pigment layer. Accordingly, because there is no need to apply the transparent resin over the planarizing layer, the thickness of the color filter layer can be further thinned.

The glass transition temperature of the transparent resin material used for the underlying layer is not particularly limited. However, it is necessary to avoid exposing an entire device to a high temperature. In addition, when considering a temperature range that the adhesive strength of the pigment layer can be improved, the glass transition temperature of 200° C. or below is particularly preferred. Accordingly, by heat fusing the pigment layer on the underlying layer made of the transparent resin at the temperature of 200° C. or below, the temperature being at or above the glass transition temperature of the transparent resin, an influence due to heat on other elements can be reduced.

The glass transition temperature of the transparent resin is preferably lower than the sublimation point of the pigment contained in the pigment layer. When the glass transition temperature of the transparent resin is lower than the sublimation point of the pigment, lightening of the color filter does not occur in conjunction with sublimation of the pigment by heat fusing the pigment layer on the underlying layer within this temperature range.

The thickness of the underlying layer is not particularly limited as long as the film thickness is capable of film formation by coating, and a film thickness of 5 nm or more and 100 nm or less is especially preferable.

In the structure described above, the transparent resin preferably includes an infrared absorption agent. In general, because it is essential that an infrared cut filter be inserted along an optical path of incident light in order to capture a color image using an imaging device, the infrared cut filter must normally be provided as a separate component from the imaging device.

In the above structure relating to the present invention, the infrared cut filter can be formed within the imaging device in the formation of the underlying layer by using the transparent resin that contains the infrared absorption agent. This enables a thinner camera module to be constructed compared to a camera module in which the infrared cut filter and the imaging device are provided separately.

As the infrared absorption agent, there may be used a compound of anthraquinone series, compound of phthalocyanine series, compound of cyanine series, compound of polymethylene series, compound of aluminum series, compound of di-imonium series, compound of imonium series, compound of azo series, or the like. In order to add infrared absorption functionality, forming the underlying layer is preferred to be by a composition, such as an acrylic resin, containing at least one of the above compounds.

Further, a fabricating method of a color imaging device relating to the present invention is a fabricating method of a color imaging device in which a color filter layer is formed respectively for a plurality of photoelectric conversion elements arranged on a substrate. A formation process of the color filter layer comprises the steps of forming an underlying layer of a transparent resin on a substrate in which the plurality of the photoelectric conversion elements are arranged and heat-fusing a pigment layer on the underlying layer at or above a glass transition temperature of the transparent resin constituting the underlying layer.

According to this fabricating method of a color imaging device, in the heat-fusing at or above the glass transition temperature of the transparent resin constituting the underlying layer, the transparent resin becomes fluid. In this state, the pigment layer formed on the underlying layer penetrates into the underlying layer which has turned into a gummy resin, thereby generating the anchoring effect. Accordingly, the problem in which the pigment layer is exfoliated from the underlying layer is eliminated even when the pigment layer is patterned. As a result, the color filter can be obtained which has excellent adhesiveness between the pigment layer and the substrate and has a thinner film thickness on the photoelectric conversion element. Further, a color imaging device can be obtained that provides this color filter. In this case, when the glass transition temperature of the transparent resin is lower than the sublimation point of the pigment, lightening of the color filter does not occur in conjunction with sublimation of the pigment by heat fusing within the above described temperature range.

The type of transparent resin used as the underlying layer is not particularly limited so long as film formation is possible by coating. For example, a thermosetting resin or the like may be used as the transparent resin. For example, as the thermosetting resin, there may be used phenol resin, urea resin, diallyl phthalate resin, melamine resin, guanamine resin, unsaturated polyester series resin, polyurethane series resin, epoxy resin, aminoalkyd resin, melamine/urea co-condensed resin, silicon resin, polysiloxane resin, or the like. As additives, there may be added curing agents, such as cross linking agents and polymerization initiators, polymerization accelerators, solvents, viscosity modifiers, extender pigments, and the like. As curing agents, isocyanate is commonly used for unsaturated polyester series resin or polyurethane series resin. Also, as curing agents peroxide such as methyl ethyl ketone peroxide or a radical initiator such as azobisisobutyronitrile is commonly used for unsaturated polyester series resins. The sublimation point of the pigment contained in the pigment layer is preferably 250° C. or more.

With this fabricating method, a pigment not suited for use in a photoresist due to its poor distributive properties may be used because distributing the pigment in a photosensitive resin is not required. Therefore, a scope of selection of a pigment for the pigment layer is broadened while enabling easy design of pigment composition to obtain more preferable spectral characteristics.

With the fabricating method described above, the underlying layer is preferably a planarizing layer formed on the substrate in which the plurality of the photoelectric conversion elements is arranged.

When the underlying layer is formed as the planarizing layer of the transparent resin, a fabrication process can be shortened because there is no need to further apply a transparent resin onto the planarizing layer.

With the fabricating method described above, the pigment layer is preferably a vapor-deposited pigment film formed by heat fusing the pigment on the underlying layer. With this configuration, the pigment layer, which contains a pigment as a main component material (that does not contain a photo active component, curing agent, and the like), can be formed, and a thinner color filter can be specifically realized. Moreover, the vapor-deposited pigment film may be provided by deposition of only the pigment. The glass transition point of the transparent resin material used as the underlying layer is not particularly limited. However, it is necessary to avoid exposing an entire device to a high temperature. In addition, when considering a temperature range that the adhesive strength of the pigment layer can be improved, the heat treatment temperature for heat fusing the pigment layer to the underlying layer is especially preferred to be 200° C. or less.

Further, the heat treatment temperature for heat fusing is preferably at or below the sublimation point of the pigment contained in the pigment layer. With this configuration, because a temperature for heat fusing is at or above the glass transformation temperature of the transparent resin of the underlying layer and at or below the sublimation point of the pigment of the pigment layer, lightening of the color filter does not occur in conjunction with sublimation of the pigment.

According to the present invention, a thinning of the color filter can be realized by adopting a structure where the color filter includes the pigment layer and the underlying layer in a color imaging device. Accordingly, because the film thickness on the photoelectric conversion element can be thinned, an improvement to sensitivity can be realized (or desensitization can be avoided). Further, by performing heat fusing using heat treatment at a temperature that is at or above the glass transition temperature of the transparent resin constructing the underlying layer, the anchoring effect can be obtained at an interface between the pigment layer and the underlying layer enabling an increase in adhesiveness of the pigment layer on the substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial cross-sectional view showing a color imaging device in an embodiment relating to the present invention.

FIG. 2 is a view showing an example of a planar arrangement of colors for each pixel of a color filter provided with a color imaging device in an embodiment relating to the present invention.

FIGS. 3A to 3D are views explaining a fabricating method of a color filter provided with a color imaging device in an embodiment relating to the present invention.

FIG. 4 is a partial cross-sectional view showing a conventional color imaging device.

FIGS. 5A to 5E are views showing an example of a fabricating method of a conventional color imaging device.

FIGS. 6A to 6F are views showing another example of a fabricating method of a conventional color imaging device.

### DETAILED DESCRIPTION OF PREFERRED EMBODIMENTS

A description is provided hereafter, with reference to drawings, of a color imaging device 100 and a fabricating method thereof in an embodiment relating to the present invention.

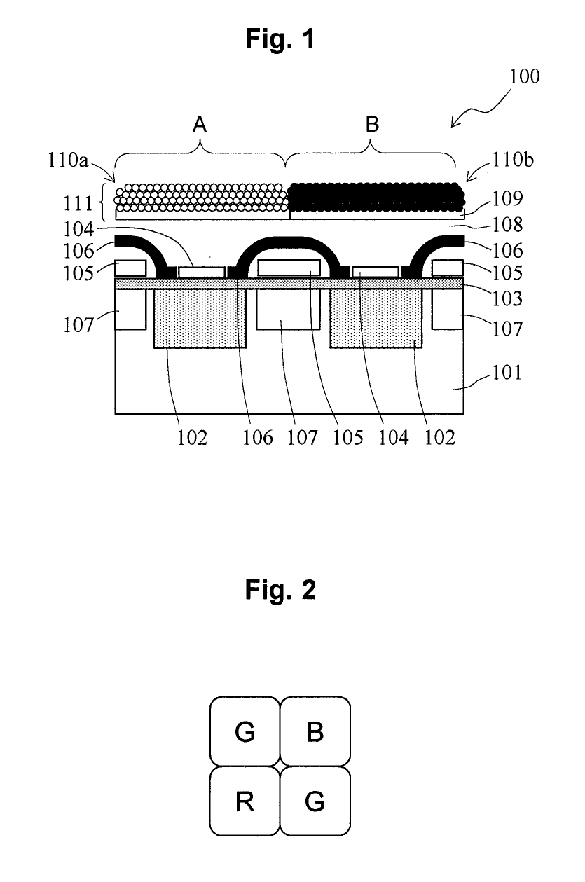

FIG. 1 shows a partial cross-sectional view showing a structure of the color imaging device 100 relating to the present invention. The color imaging device 100 is formed by using a semiconductor substrate 101 of silicon. A plurality of photoelectric conversion elements 102 for generating electric charges according to incident light is arranged in a matrix configuration and provided in a surface portion of the semiconductor substrate 101. A single pixel will normally provide a single photoelectric conversion element 102. FIG. 1 shows a region that corresponds to nearly 2 pixels (pixel A and pixel B) of the color imaging device 100.

On the semiconductor substrate 101, a dielectric film 103 covering the photoelectric conversion element 102 is formed. An anti-reflection film 104 for inhibiting reflection of light which enters the photoelectric conversion element 102 is formed on the photoelectric conversion element 102 with the dielectric film 103 interposed therebetween. A charge transfer electrode 105 for reading out the electric charges from each photoelectric conversion element 102 and transferring the readout electric charges is formed on areas of both sides of the photoelectric conversion element 102 on the semiconductor substrate 101 with the dielectric film 103 interposed therebetween. Further, a light shielding film 106 that shields light from entering the charge transfer electrode 105 is formed covering the charge transfer electrode 105. A charge transfer path 107, by which the readout electric charges are transferred, is provided in the semiconductor substrate 101 below the charge transfer electrode 105. The charge transfer path 107 extends, in regards to FIG. 1, in an orthogonal direction to the surface of the paper.

A transparent planarizing layer 108 for planarization of a surface is formed covering the anti-reflection film 104 and the light shielding film 106 and the like. A color filter 111 is formed on the planarizing layer 108. Although omitted in FIG. 1, a micro lens is formed over each color filter 111 for improving a light condensing efficiency for each photoelectric conversion element 102.

The color filter 111 of the this embodiment has a multilayer structure consisting of an underlying layer 109 made of a transparent resin and a pigment layer 110a (schematically illustrated as an aggregate of white circles representing pigment) or a pigment layer 110b (schematically illustrated as an aggregate of black circles representing pigment) formed per each pixel on the underlying layer 109. In FIG. 1, the pigment layer 110a is formed corresponding to the pixel A and the pigment layer 110b is formed corresponding to the pixel B.

The pigment layers 110a and 110b are arranged on a plane and a predetermined single color is used for individual pixels. For example, three colors of red (R), blue (B) and green (G) are arranged on a plane by repeating a pattern showing in FIG. 2. As another example, four colors of magenta, cyan, yellow and green may be used. The effectiveness obtained on the color imaging device 100 of this embodiment is not particularly related to a combination or arrangement of the colors to be used. Therefore, in FIG. 1, a case that the pigment layer 110a is formed as a first color for the pixel A and the pigment layer 110b is formed as a second color for the pixel B is shown. Furthermore, use of a pigment layer of a third color is of course possible.

Herein, both the pigment layer 110a and the pigment layer 110b in this embodiment respectively contain a pigment as a main component material, and do not contain a photo active compound and curing agents. Therefore, a thickness of the pigment layer 110a, 110b can be made thinner compared to a color filter made of a photosensitive resin that contains pigment.

As a result, because thinning of the film of the color filter 111 is realized as well as thinning of the layer on the photoelectric conversion element 102, desensitization that accompanies the micronization of pixels can be avoided. Moreover, dye layers 110a and 110b may be made solely from dye.

In addition, the thickness of the underlying layer 109 made of the transparent resin can be made thinner because the underlying layer 109 may have a film thickness that enables film formation by coating. Therefore, the thinning of the film thickness of the color filter 111 is realized, so that a thickness of layers on the photoelectric conversion element 102. As a result, desensitization which accompanies micronization of pixels can be avoided. Moreover, the pigment layers 110a and 110b may be composed solely of a pigment.

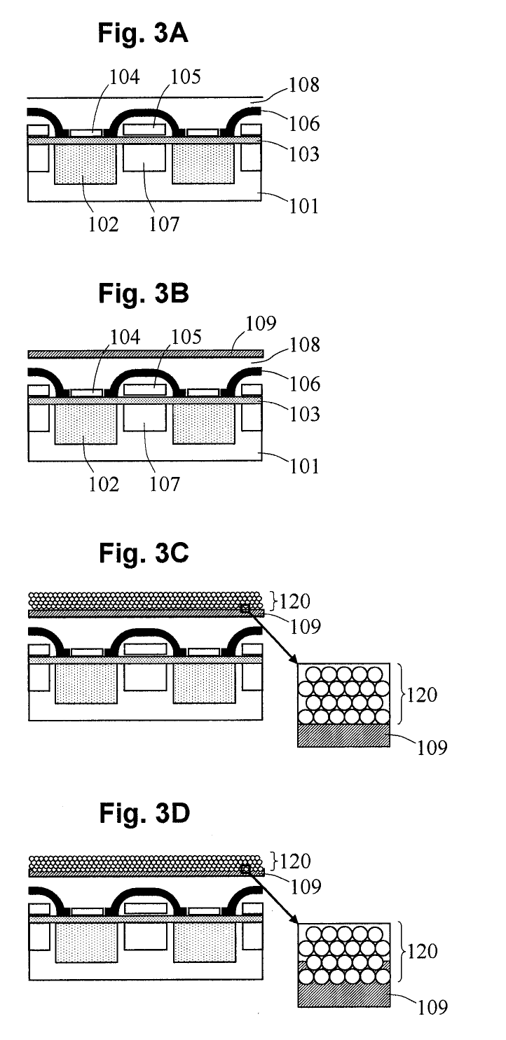

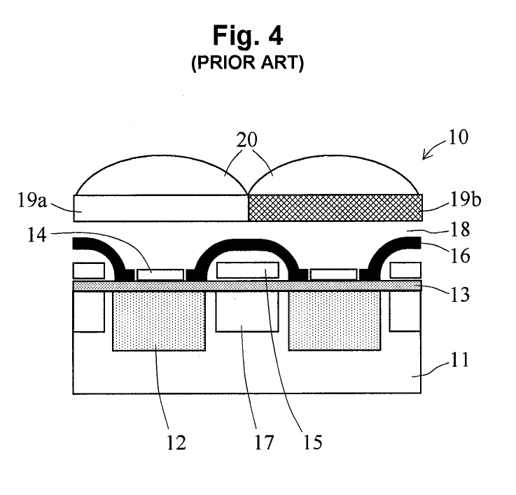

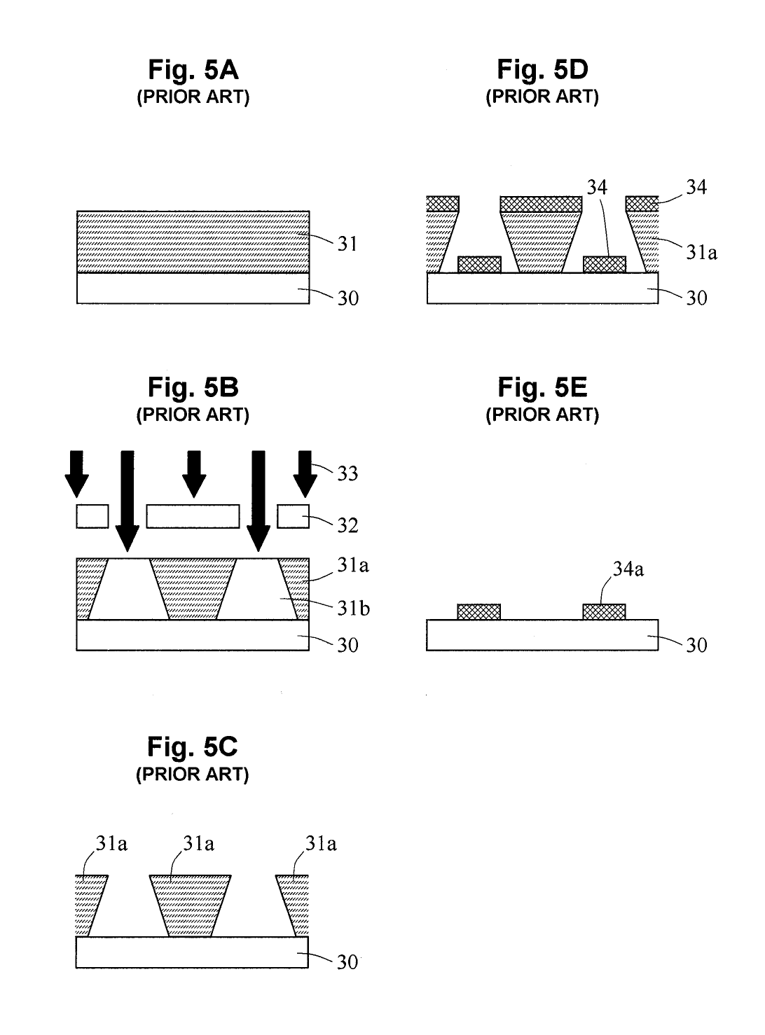

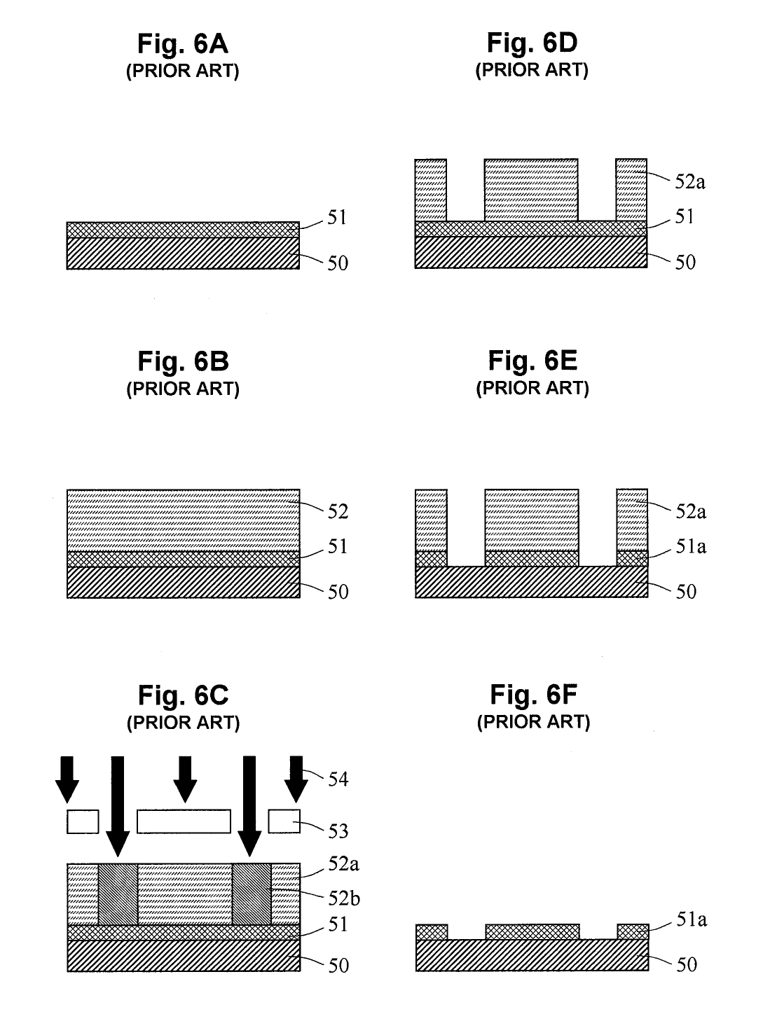

A description will be given hereafter of a fabricating method of the color imaging device 100 having the structure described above. FIGS. 3A to 3D are partial cross-sectional views explaining a fabricating process of the color imaging device 100 of the present embodiment. In FIGS. 3A to 3D, components which have an equivalent in FIG. 1 have the same reference number.

FIG. 3A shows a state of the color imaging device 100 completed through formation of the planarizing layer 108. In other words, the photoelectric conversion element 102, the dielectric film 103, the anti-reflection film 104, the charge transfer electrode 105, the light shielding film 106, the charge transfer path 107 and the planarizing layer 108 has been formed on the semiconductor substrate 101. This structure can be formed in the same manner as conventional fabricating method. The planarizing layer 108 may be formed by using a PSG (Phosphorous Silicon Glass) film or a BPSG (Boron Phosphorous Silicon Glass) film.

(Formation of the underlying layer made of the transparent resin)

Next, as shown FIG. 3B, the underlying layer 109 made of the transparent resin is formed on the planarizing layer 108 by, for example, spin coating method. With this embodiment, acrylic/methacrylic copolymers having a glass transition point of 120° C. is used as a material to compose the underlying layer.

(Formation of the pigment layer)

Next, as shown FIG. 3C, a pigment layer 120 of the first color is formed on the underlying layer 109. The pigment layer 120 may be formed by vapor deposition method as one example. Herein, halogenated phthalocyanine is vapor-deposited as a pigment of the first color to form the pigment layer 120 of a vapor-deposited pigment film having a thickness of 200 nm to 600 nm.

Heat fusing)

Next, as shown FIG. 3D, after the formation of the pigment layer for the first color (for example, green), heat the substrate in a bake furnace to 180° C., which is the temperature at or above the glass transition point of the transparent resin material, to perform heat processing to the underlying layer 109. By so doing, an anchoring effect is generated by embedding the pigment constructing the pigment layer 120 into the underlying layer 109 enabling a color filter to be obtained that has increased adhesiveness at an interface between the underlying layer 109 and the pigment layer 120.

(Patterning of the color filter)

Next, the pigment layer is patterned by the method described above. The pigment layer which does not have photographic potential can be patterned by using the above mentioned method such as a method that uses the lift-off and a method that removes a part of the pigment layer by dry etching. With either method, color filters of predetermined colors can be formed in order. For example, patterning is performed to a pigment layer made of a green pigment vapor-deposited as the first color, and thereafter the same process is repeated using in order a pigment layer made of a red pigment and a pigment layer made of a blue pigment. By combining these three processes, the color filter having patterns of green, red and blue can be formed.

In the color filter formation process, a color formation order is not particularly limited. However, when considering an exfoliation resistance to resist developing solution and resist removing solution of the pigment in use, it is preferable to form the color filter in an order of the pigment with the strongest exfoliation resistance to the pigment with the weakest exfoliation resistance. For example, there is phthalocyanine as a pigment with a strong exfoliation resistance, and there is perylene as a pigment with a weak exfoliation resistance.

(Formation of the micro lens)

First, a photosensitive synthetic resin film made of an acrylic transparent resin is formed all over the color filter by spin coating and dried in a low temperature. Thereafter, by exposing the synthetic resin film using ultraviolet light such as a g-line (wavelength 436 nm), i-line (wavelength 365 nm) or the like with a photomask having a desired pattern, an independent segregated synthetic resin film pattern is formed per each pixel. Next, by irradiating an entire surface of the synthetic resin film with ultraviolet light, a transmittance in the visible light region of the synthetic resin film is improved to 90% or more in the entire surface. Next, a micro lens is formed by heating-melting process (reflow) across the entire surface to cause heat deformation of the synthetic resin film to form a convex hemispherical shape having a desired curvature.

Through the above-described process, the color imaging device of the present embodiment that provides the color filter can be obtained.

(Example 1)

In Example 1, an imaging device is created by the same method as the above- described embodiment.

(Example 2)

In Example 2, the planarizing layer 108, which is the underlying layer, made of an acrylic/methacrylic copolymer having the glass transition point of 120° C. is formed on the substrate and the pigment layer is formed on the planarizing layer 108. Also, in the above heat fusing process, the heat treatment is performed to the planarizing layer at 180° C. which is a temperature at or above the glass transition point of the resin constructing the planarizing layer. An imaging device in Example 2 is created by the same method as Example 1 from the color filter patterning process to the micro lens formation process.

(Comparative example 1)

The underlying layer made of the transparent resin which is an acrylic/methacrylic copolymer having the glass transition point of 120° C. is formed on the planarizing layer 108. After a formation of the pigment layer, patterning is performed to the pigment layer without heat treatment. An imaging device in Comparative example 1 is created by the same method as Example 1 from the color filter patterning process to the micro lens formation process.

(Comparative example 2)

The pigment layer is formed on the planarizing layer 108, which is the underlying layer, made of an acrylic/methacrylic copolymer having the glass transition point of 120° C. The patterning of the pigment layer is performed without heat treatment. An imaging device in Comparative example 2 is created by the same method as Example 1 from the color filter patterning process to the micro lens formation process.

The anchoring effect was not able to be confirmed for the color filters of the imaging devices in Comparative examples 1 and 2.

(Adhesion testing)

In order to confirm that adhesiveness of the pigment layer relating to this invention is increased, a cellophane tape adhesion test (JIS K5600-5-6) using a cross-cut method was performed on the imaging devices obtained by Examples 1, 2 and Comparative examples 1, 2. The results are shown in Table 1. The values in the table are the cross-cut counts in which the pigment layer did not exfoliate when stripped by the cellophane tape from among 100 cross-cuts per an imaging device.

TABLE 1

| | | | Comparative | Comparative |
|---|---|---|---|---|
| | Example 1 | Example 2 | example 1 | example 2 |
| Cellophane tape | 100/100 | 100/100 | 50/100 | 50/100 |
| adhesion test | | | | |
| (cross-cut) | | | | |

According to Table 1, the adhesiveness of the pigment layer to the substrate is confirmed to be stronger in the imaging devices of Example 1 and Example 2, relating to the present invention, fabricated by forming the pigment layer on the underlying layer then performing heat treatment at the temperature that is at or above the glass transition point of the transparent resin constructing the underlying layer, compared to the imaging devices of Comparative example 1 and Comparative example 2 fabricated by forming the pigment layer using the conventional vapor deposition method that does not perform the heat treatment relating to present invention.

According to an imaging device and a fabricating method thereof in the present invention, because the imaging device is capable of providing that has a thinner color filter and stronger adhesiveness of the pigment layer, desensitization due to micronization of the pixels can be avoided which is useful to high resolution digital cameras and video cameras and the like. Further, the present invention is not only suited to CCD type and MOS type image sensors, but is also suited for use in such as organic electroluminescence display devices. Therefore, the industrial applicability thereof is significant.

What is claimed is:

1. A color imaging device in which a color filter layer is formed respectively for a plurality of photoelectric conversion elements arranged on a substrate, the color filter layer comprising:
an underlying layer of a transparent resin; and
a pigment layer heat fused on the underlying layer at or above a glass transition temperature of the transparent resin constituting the underlying layer.

2. A color imaging device according to claim 1, wherein the underlying layer is a planarizing layer formed on the substrate in which the plurality of the photoelectric conversion elements is arranged.

3. A color imaging device according to claim 1, wherein the glass transition temperature of the transparent resin is at or below 200° C.

4. A color imaging device according to claim 1, wherein the glass transition temperature of the transparent resin is lower than a sublimation point of a pigment contained in the pigment layer.

5. A color imaging device according to claim 1, wherein the transparent resin contains an infrared absorption agent.

6. A fabricating method of a color imaging device in which a color filter layer is formed respectively for a plurality of photoelectric conversion elements arranged on a substrate, a formation process of the color filter layer comprising the steps of forming an underlying layer of a transparent resin on the substrate in which the plurality of the photoelectric conversion elements is arranged; and
heat-fusing a pigment layer on the underlying layer at or above a glass transition temperature of the transparent resin constituting the underlying layer.

7. A fabricating method of a color imaging device according to claim 6, wherein the underlying layer is a planarizing layer formed on the substrate in which the plurality of the photoelectric conversion elements is arranged.

8. A fabricating method of a color imaging device according to claim 6, wherein the pigment layer is formed by vapor deposition of pigment on the underlying layer.

9. A fabricating method of a color imaging device according to claim 6, wherein a heat treatment temperature for heat fusing is at or below 200° C.

10. A fabricating method of a color imaging device according to claim 6, wherein a heat treatment temperature for heat fusing is lower than a sublimation point of a pigment contained in the pigment layer.
